(19) United States
(12) Patent Application Publication
(10) Pub. No.: US 2012/0007751 A1
(43) Pub. Date: Jan. 12, 2012

(54) DE-BOUNCE CIRCUIT

(75) Inventors: Shian-Sung Shiu, New Taipei City (TW); Li-Min Lee, New Taipei City (TW); Hu Xia, Wuxi (CN)

(73) Assignee: GREEN SOLUTION TECHNOLOGY CO., LTD., New Taipei City (TW)

(21) Appl. No.: 13/031,247

(22) Filed: Feb. 21, 2011

(30) Foreign Application Priority Data
Jul. 6, 2010 (CN) 201010222524.7

(51) Int. Cl. H03K 17/94

(52) U.S. Cl. 341/20

(57) ABSTRACT

A de-bounce circuit is disclosed. The de-bounce circuit comprises a wave-shaping circuit, a filtering circuit and a trigger circuit. The wave-shaping circuit is adapted to shape a control signal and output a wave-shaping signal. The control signal may be generated from a mechanical switch. The filtering circuit charges/discharges a capacitor according to the wave-shaping signal, and determines whether to generate a judgment signal according to a voltage of the capacitor. The trigger circuit determines whether to generate an enable signal according to the number of times of the judgment signal.

### CROSS-REFERENCE TO RELATED APPLICATION

This application claims the priority benefit of China application serial no. 201010222524.7, filed on Jul. 6, 2010. The entirety of the above-mentioned patent application is hereby incorporated by reference herein and made a part of this specification.

### BACKGROUND OF THE INVENTION

(1) Field of the Invention

The present invention relates to a de-bounce circuit. More particularly, the invention relates to a de-bounce circuit with delayed judgment function.

(2) Description of the Prior Art

FIG. 1 is a schematic circuit of a conventional button switch circuit. Referring to FIG. 1, the button switch circuit provides a fast and convenient connection manner between user and the circuit. The button switch circuit includes a resistor R, a switch SW and controller 10. One terminal of the resistor R is coupled to a power source and the other is coupled to one terminal of the switch SW. Another terminal of the switch SW is coupled to ground. When user presses the switch to start the circuit, the resistor R is grounded through the switch SW, such that the connect point of the resistor R and switch SW generates a low level control signal Ssw to controller 10. The controller 10 starts the circuit operation after detecting the low-level control signal Ssw. User could stop pressing the switch SW when the circuit is started. When user presses the switch SW again to stop the circuit, the connect point of the resistor R and switch SW generates a low level control signal Ssw to controller 10, again. Therefore, the circuit stops operating after the operating controller 10 detects the low level control signal Ssw.

In general, the switch SW is mechanical structure and has a spring inside to provide a force to keep the switch at a certain state. Accordingly, When user presses or looses the switch SW, it generates a short and uncertain bounce phenomenon due to the metallic structure of the switch colliding each other. FIG. 2 is a waveform diagram of the control signal generated by the button switch circuit. Referring to FIG. 2, the level of the control signal Ssw displays the bounce phenomenon for an initial period time and then generated the stable level. The bounce phenomenon of the mechanical switch like several pulses, and so the controller 10 may make erroneous operation. To avoid the above situation, the conventional circuit increases a low-pass circuit coupled to the switch SW to filter out the high frequency noise due to the bounce phenomenon. However, low-pass circuit needs a capacitor with higher capacitance, such that the whole circuit cost is increased.

### SUMMARY OF THE INVENTION

In the foregoing related art, the bounce phenomenon of the mechanical switch causes the erroneous operation of the controller. Beside from that, when the conventional circuit uses the low-pass circuit to avoid the erroneous operation, the additional circuit cost is increased. Accordingly, an exemplary embodiment of the invention provides a circuit with built-in de-bounce circuit in the controller, so as to avoid the erroneous operation because of the bounce phenomenon. In addition to the above, the cost of built-in de-bounce circuit is far lower than the external low-pass circuit. Therefore, the whole circuit of the invention does not cause the cost increased significantly.

To accomplish the aforementioned and other objects, the present invention provides the de-bounce circuit that comprises a wave-shaping circuit, a filtering circuit and a trigger circuit. The wave-shaping circuit is adapted to shape a control signal and output a wave-shaping signal. The filtering circuit charges and discharges a capacitor according to the wave-shaping signal, and determines whether to generate a judgment signal according to a voltage of the capacitor. The trigger circuit determines whether to generate an enable signal according to the number of times of the judgment signal.

An exemplary embodiment of the invention, the filtering circuit comprises a charge circuit and discharge circuit. When the wave-shaping signal is in the first logic level, the charge circuit provides a first charge current to charge a capacitor. When the wave-shaping signal is in the second logic level, the discharge circuit provides a first discharge current to discharge a capacitor.

An exemplary embodiment of the invention, the trigger circuit is a D flip-flop. The trigger circuit also comprises an assistant charge circuit and/or an assistant discharge circuit. In the appropriate time, the capacitor is charged and/or discharged according to the corresponding assistant charge circuit and/or the corresponding assistant discharge circuit.

It is to be understood that both the foregoing general description and the following detailed description are exemplary, and are intended to provide further explanation of the invention as claimed. In order to make the features and the advantages of the invention comprehensible, exemplary embodiments accompanied with figures are described in detail below.

### BRIEF DESCRIPTION OF THE DRAWINGS

The present invention will now be specified with reference to its preferred embodiment illustrated in the drawings, in which:

FIG. 1 is a schematic circuit of a conventional button switch circuit.

FIG. 2 is a control signal waveform diagram of the button switch circuit shown in FIG. 1.

FIG. 3 is a schematic diagram of a de-bounce circuit according to a first embodiment of the invention.

FIG. 4 is a signal waveform diagram of the de-bounce circuit shown in FIG. 3.

FIG. 5 is a schematic diagram of a de-bounce circuit according to another embodiment of the invention.

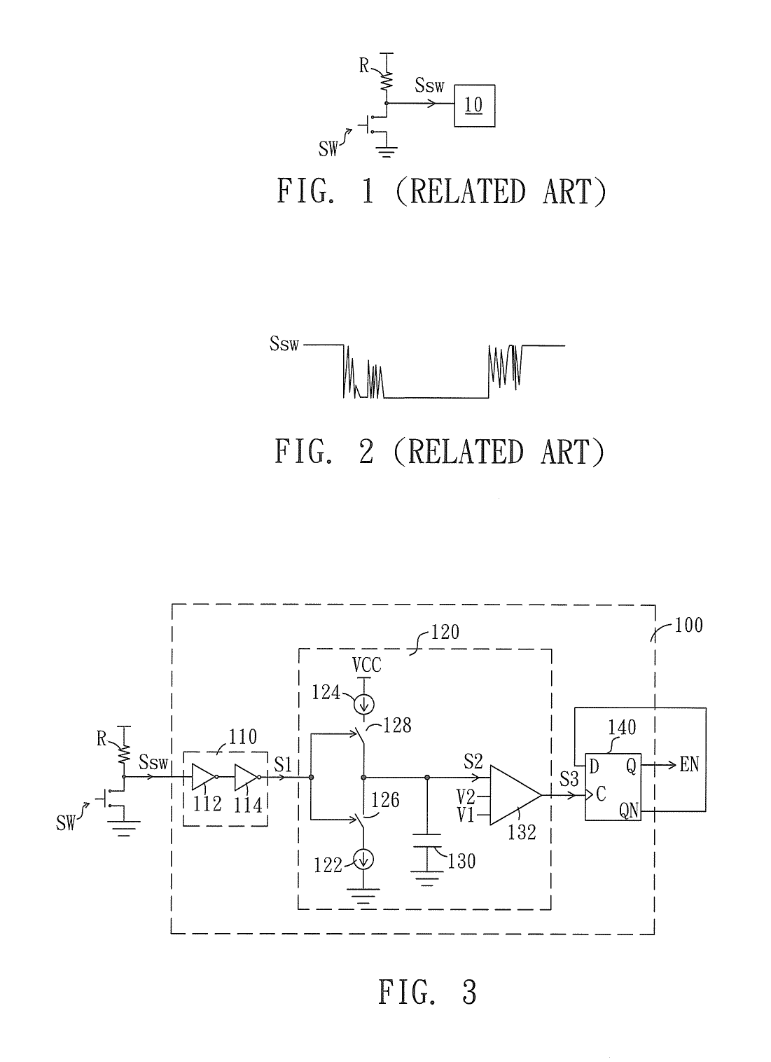

### DESCRIPTION OF THE PREFERRED EMBODIMENT

FIG. 3 is a schematic diagram of a de-bounce circuit according to a first embodiment of the invention. Referring to FIG. 3, the de-bounce circuit 100 includes a wave-shaping circuit 110, a filtering circuit 120 and a trigger circuit 140. The de-bounce circuit 100 receives a control signal Ssw which is generated by a connection point of a switch SW and resistor R, wherein one terminal of the switch SW is coupled to a power source through the resistor R and another terminal of the switch SW is grounded. The wave-shaping circuit 110 is coupled to the switch SW to receive the control signal Ssw, so as to shape a control signal Ssw and output a wave-shaping signal S1. The filtering circuit 120 is coupled to the wave-shaping circuit 110, so as to receive the wave-shaping signal S1. The filtering circuit 120 charges and discharges the capacitor 130 according to the wave-shaping signal S1. Therefore, the voltage of the capacitor 130 is increased or decreased according to the wave-shaping signal S1, i.e. the control signal Ssw. When the voltage of the capacitor 130 is raised to a predetermined voltage, the filtering circuit 120 generates a judgment signal S3. The trigger circuit 140 is coupled to the filtering circuit 120 to receive the judgment signal S3. The judgment signal S3 triggers the trigger circuit 140 to switch the state between generating an enable signal EN and stopping to generate the enable signal EN. That is, the trigger circuit 140 determines whether to generate the enable signal EN according to the number of times of the judgment signal S3.

In the present embodiment, the wave-shaping circuit 110 includes a first inverter 112 and a second inverter 114. An input terminal of the first inverter 112 receives the control signal Ssw and an output terminal of the first inverter 112 is coupled to an input terminal of the second inverter 114. An output terminal of the second inverter 114 is coupled to the filtering circuit 120 and generates the wave-shaping signal S1. The filtering circuit 120 includes a charge circuit and a discharge circuit. The discharge circuit includes a discharge current source 122 and a discharge switch 126. The charge circuit includes a charge current source 124 and a charge switch 128. The filtering circuit 120 also includes a capacitor 130 and a comparator 132. The discharge switch 126 and the charge switch 128 is switched between the turn-on state and the turn-off state according to the wave-shaping signal S1, so as to decide to discharge the capacitor 130 by the discharge current source 122 or charge the capacitor 130 by the charge current source 124. For example, the discharge switch 126 and the charge switch 128 are n-channel metal-oxide semiconductor (NMOS) and p-channel metal-oxide semiconductor (PMOS) respectively. When the wave-shaping signal S1 is a low level (i.e. a first logic level), the charge switch 128 is turned-on and the discharge switch 126 is turned-off. At this moment, the capacitor 130 is charged by the charge current source 124, such that the voltage of the capacitor 130 is increased. When the wave-shaping signal S1 is a high level (i.e. a second logic level), the charge switch 128 is turned-off and the discharge switch 126 is turned-on. At this moment, the capacitor 130 is discharged by the charge current source 122, such that the voltage of the capacitor 130 is decreased. The comparator 132 can be a hysteresis comparator. The comparator 132 receives a voltage of a level signal S2 from the capacitor 130 and compared with a high reference voltage V2 and a low reference voltage V1. Wherein, the high reference voltage V2 is higher than the low reference voltage V1. The trigger circuit 140 can be a D flip-flop. The clock control terminal C of the D flip-flop receives the judgment signal S3. The input terminal D is coupled to the inverting output terminal QN, and the output terminal Q outputs the enable signal EN. Therefore, the output terminal Q of the D flip-flop outputs the enable signal EN, (i.e. the output terminal Q is high level) or stops outputting the enable signal EN, (i.e. the output terminal Q is low level) by the generated times of the judgment signal S3

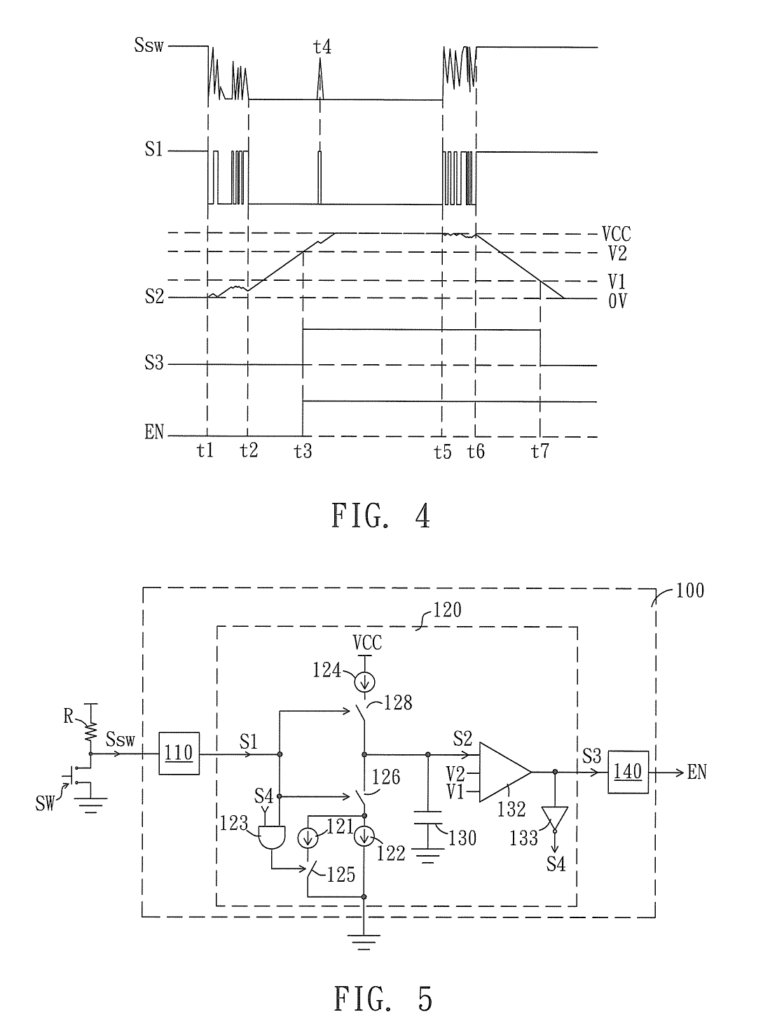

Next, FIG. 4 is a signal waveform diagram of the de-bounce circuit shown in FIG. 3. Referring to FIG. 4, the initial state of the enable signal EN of the de-bounce circuit 100 is low level. The initial state of the switch SW is open-circuit, such that the control signal Ssw is high level. At time point t1, user presses the switch SW, such that the resistor R is grounded through the switch SW. Then, the control signal Ssw appears the de-bounce phenomenon until time point t2 and then is stabilized at a low level. During the period from time point t1 to time point t2, the level of the wave-shaping signal S1 swings within the range between the low level and the high level due to the de-bounce phenomenon of the control signal Ssw. The wave-shaping signal S1 is not stabilized at the low level until time point t2. Beside from that, during the period from time point t1 to time point t2, the charge and discharge process of the capacitor 130 also perform interlacedly due to that the wave-shaping signal S1 swings and so the voltage of the level signal S2 shake above the zero voltage. After time point t2, the wave-shaping signal S1 is maintained low level, such that the capacitor 130 keeps in the charge state, and so the level signal S2 starts to be increased continuously. At time point t3, the level signal S2 is raised to the high reference voltage V2, such that the comparator 132 output a high level judgment signal S3. A period from time point t2 to t3 is a delay time of the de-bounce circuit for judging the pressed time of which the switch SW. The delay time may be adjusted by modulating the capacitance of the capacitor 130 and/or the values of the charge current. In order to avoid to increase die area substantially due to that the capacitor 130 is built in the integrated circuit, the values of the charge current may be reduced to reduce the capacitance (i.e. area) of the capacitor 130. When the clock control terminal C of the trigger circuit 140 receives a high level judgment signal S3, the input terminal D detects the level of the inverting output terminal QN. Due to the inverting output terminal QN is high level at this moment, the output terminal Q of the trigger circuit 140 outputs a high-level enable signal EN and the inverting output terminal QN turns into low level. When the control signal Ssw is generated a noise at time point t4, the wave-shaping signal S1 appears a pulse. Because the width of the pulse is short, the capacitor 130 is just discharged shortly. This short discharge does not enough to let the level signal S2 decrease to low reference voltage V1. Thus, the judgment signal S3 is still maintained high level. When the trigger circuit 140 output the high level enable signal EN, the system starts operation. Next, the user looses the switch SW at time point t5, such that the resistor R is not grounded through the switch SW. At this time, the control signal Ssw is raised and then appears the de-bounce phenomenon. The control signal Ssw is not stabilized at the high level until time point t6. The same as above, during the period from time point t5 to time point t6, the level signal S2 shakes below the power source VCC and the level signal S2 starts to continuously decrease after time point t6. At time point t7, when the level signal S2 is decreased to the low reference voltage V1, the comparator 132 stops outputting the judgment signal S3, (i.e. output the low level judgment signal S3.) Similarly, the period from time point t6 to t7 is a time delay of the de-bounce circuit for judging the loosed time of which the switch SW. The delay time may be adjusted by modulating the capacitance of the capacitor 130 and/or the values of the discharge current. After time point t7, the capacitor 130 is not stopped discharging until the level signal S2 is decreased to close the 0 volt. Although the comparator 132 stops outputting the judgment signal S3, the trigger circuit 140 is just triggered by the rising edge of the judgment signal S3 and the trigger circuit 140 still outputs the high-level enable signal EN, so as to maintain the system operation.

When user wants to stop the system operating, user may press the switch SW again. At this moment, the signal waveform of the control signal Ssw, wave-shaping signal S1, level signal S2 and judgment signal S3 appear such as that shown in FIG. 4. The only difference is described below. When the trigger circuit 140 is triggered by high level judgment signal S3, the inverting output terminal QN is low level and so the trigger circuit 140 outputs the low-level enable signal EN, and then the system stops operation.

FIG. 5 is a schematic diagram of a de-bounce circuit according to another embodiment of the invention. Referring to FIG. 5, compared with the de-bounce circuit as shown in FIG. 3, the de-bounce circuit of the embodiment increases an assistant discharge circuit and a corresponding controller. The assistant discharge circuit includes an assistant discharge current source 121 and assistant discharge switch 125. Wherein, the discharge current of the assistant discharge current source 121 is larger than that of the discharge current source 122. The main purpose of the assistant discharge circuit is to avoid the time length from time point t2 being uncertain due to the imbalance of the charge/discharge during the period from time point t1 to time point t2 as shown in FIG. 4. Even during the period from time point t1 to time point t2, the level signal S2 may be raised to the high reference voltage V2. Therefore, during the period from time point t1 to time point t2, The additional assistant discharge current source 121 makes the discharge current of the discharge process larger than the charge current of the charge process and so ensures that the start point (i.e. time point t2) of the level signal S2 is close to zero voltage. Therefore, the time length from t2 to t3 is almost the same in the present embodiment. After the time point t3, the level signal S2 is raised to be above the high reference voltage V2. The over discharge current causes the level signal S2 down to the low reference voltage V1, such that the judgment signal S3 is turned to the low level to cause erroneous determination of the system. In order to avoid the foregoing problem, the assistant discharge circuit should be stopped. As shown in FIG. 5, the controller, for controlling the assistant discharge circuit, includes an AND gate 123 and an inverter 133. An input terminal of the inverter 133 is coupled to the output terminal of the capacitor 132 and an output terminal of the inverter 133 is coupled to one input terminal of the AND gate 123. Another input terminal of the AND gate 123 receives wave-shaping signal S1 and an output terminal of the AND gate 123 outputs a signal, so as to control the assistant discharge switch 125. When the level signal S2 does not reach the high reference voltage V2 yet, the judgment signal S3 is low level. Next, the level signal S2 is inverted to a high-level assistant discharge signal S4 through the inverter 133, which is then inputted the AND gate 123. At this moment, according to the wave-shaping signal S1 the AND gate 123 control the assistant discharge switch 125 to be turned-on or turned-off. When the wave-shaping signal S1 is high level, the assistant discharge switch 125 and discharge switch 126 are simultaneously turned-on, such that the assistant discharge current source 121 and discharge current source 122 discharge the capacitor 130 at the same time. At this moment, the charge switch 128 is turned-off, and the charge current source 124 stops charging the capacitor 130. When the wave-shaping signal S1 is low level, the assistant discharge switch 125 and discharge switch 126 are simultaneously turned-off, such that the assistant discharge current source 121 and discharge current source 122 stop discharging the capacitor 130 at the same time. At this moment, the charge switch 128 is turned-on, and the charge current source 124 charges the capacitor 130. When the level signal S2 reaches the high reference voltage V2, the judgment signal S3 is high level. The level signal S2 is inverted to a low-level assistant discharge signal S4 through the inverter 133, which is then inputs the AND gate 123. At this moment, the output of the AND gate 123 is maintained low level regardless of the logic state of the wave-shaping signal S1, so as to keep the assistant discharge switch 125 being turned-off. Accordingly, the assistant discharge current source 121 does not discharge the capacitor 130 any more once the level signal S2 reaches the high reference voltage V2 to avoid the foregoing problem.

The above assistant discharge circuit could just has the assistant discharge switch 125, i.e. abridging the assistant discharge current source 121, to perform the function of assistant discharge. In the same way, in order to avoid the time length from t6 to t7 being uncertain due to the imbalance of the charge/discharge during the period from time point t5 to time point t6 as shown in FIG. 4. An exemplary embodiment of the invention also increases an assistant charge circuit and a corresponding controller, so as to provide an assistant charge current according to the wave-shaping signal S1 when the judgment signal S3 is high level. Wherein, the assistant charge current is larger than the charge current of the charge current source 124. In addition to the above, the cost with built-in de-bounce circuit is far lower than that of the external low-pass circuit. Therefore, the whole circuit for the invention does not cause the cost significant increase.

As the above description, the invention completely complies with the patentability requirements: novelty, non-obviousness, and utility. It will be apparent to those skilled in the art that various modifications and variations can be made to the structure of the invention without departing from the scope or spirit of the invention. In view of the foregoing descriptions, it is intended that the invention covers modifications and variations of this invention if they fall within the scope of the following claims and their equivalents.

What is claimed is:

1. A de-bounce circuit, comprising:
a wave-shaping circuit, adapted to shape a control signal and output a wave-shaping signal;
a filtering circuit, charging and discharging a capacitor according to the wave-shaping signal, and determining whether to generate a judgment signal according to a voltage of the capacitor; and
a trigger circuit, determining whether to generate an enable signal according to the number of times of the judgment signal.

2. The de-bounce circuit according to claim 1, wherein the filtering circuit includes a charge circuit and a discharge circuit, the charge circuit provides a first charge current to charge the capacitor when the wave-shaping signal is in a first logic level, and the discharge circuit provides a first discharge current to discharge the capacitor when the wave-shaping signal is in a second logic level.

3. The de-bounce circuit according to claim 2, wherein the filtering circuit further includes a hysteresis comparator, having an input terminal coupled to the capacitor, and an output terminal coupled to the trigger circuit.

4. The de-bounce circuit according to claim 2, wherein the trigger circuit is a D flip-flop, having a clock control terminal for receiving the judgment signal, an inverting terminal, an input terminal coupled to the inverting terminal, and an output terminal for outputting the enable signal.

5. The de-bounce circuit according to claim 2, wherein the wave-shaping circuit includes a first inverter and a second inverter, in which an input terminal of the first inverter receives the control signal, an output terminal of the first inverter is coupled to an input terminal of the second inverter, and an output terminal of the second inverter is coupled to the filtering circuit.

6. The de-bounce circuit according to claim 2, wherein the filtering circuit further includes an assistant charge circuit, providing a second charge current to charge the capacitor only when the judgment signal is generated and the wave-shaping signal is in the first logic level, in which the second charge current is larger than the first charge current.

7. The de-bounce circuit according to claim 6, wherein the filtering circuit further includes a hysteresis comparator, having an input terminal coupled to the capacitor, and an output terminal coupled to the trigger circuit.

8. The de-bounce circuit according to claim 6, wherein the trigger circuit is a D flip-flop, having a clock control terminal for receiving the judgment signal, an inverting terminal, an input terminal coupled to the inverting terminal, and an output terminal of the D flip-flop for outputting the enable signal.

9. The de-bounce circuit according to claim 6, wherein the wave-shaping circuit includes a first inverter and a second inverter, in which an input terminal of the first inverter receives the control signal, an output terminal of the first inverter is coupled to an input terminal of the second inverter, and an output terminal of the second inverter is coupled to the filtering circuit.

10. The de-bounce circuit according to claim 2, wherein the filtering circuit further includes an assistant discharge circuit providing a second discharge current to discharge the capacitor only when the judgment signal is not generated and the wave-shaping signal is in the second logic level, in which the second discharge current is larger than the first discharge current.

11. The de-bounce circuit according to claim 10, wherein the filtering circuit further includes a hysteresis comparator, having an input terminal coupled to the capacitor, and an output terminal coupled to the trigger circuit.

12. The de-bounce circuit according to claim 10, wherein the trigger circuit is a D flip-flop, having a clock control terminal for receiving the judgment signal, an inverting terminal, an input terminal coupled to the inverting terminal, and an output terminal for outputting the enable signal.

13. The de-bounce circuit according to claim 10, wherein the wave-shaping circuit includes a first inverter and a second inverter, in which an input terminal of the first inverter receives the control signal, an output terminal of the first inverter is coupled to an input terminal of the second inverter, and an output terminal of the second inverter is coupled to the filtering circuit.
